(19) United States
(12) Patent Application Publication
(10) Pub. No.: US 2022/0227081 A1
(43) Pub. Date: Jul. 21, 2022

(54) METHOD OF REPLICATING OPTICAL ELEMENTS AND REPLICATED OPTICAL ELEMENTS

(71) Applicant: ams Sensors Singapore Pte. Ltd., Singapore (SG)

(72) Inventors: Tae Yong Ahn, Eindhoven (NL); Sai Mun Chan, Eindhoven (NL); Lorenzo Tonsa, Zurich (CH); Lili Chong, Eindhoven (NL); Woei Quan Kong, Eindhoven (NL); Chitra Nadimuthu, Eindhoven (NL); Kay Khine Aung, Eindhoven (NL); Herng Wei Pook, Eindhoven (NL); Uros Markovic, Zurich (CH)

(21) Appl. No.: 17/614,738

(22) PCT Filed: May 19, 2020
(86) PCT No.: PCT/SG2020/050299

§ 371 Date: Nov. 29, 2021

Related U.S. Application Data
(60) Provisional application No. 62/854,446, filed on May 30, 2019.

(51) Int. Cl. B29D 11/00; G02B 3/00; G02B 1/10

(52) U.S. Cl. CPC B29D 11/00375; B29D 11/00298; G02B 1/10; G02B 3/0031; G02B 3/0056; B29D 11/00865

(57) ABSTRACT

Flow barriers such as trenches (144) and/or walls (152) laterally surrounding an aperture (142) in a coating (140) on a transparent substrate (120) help control the flow of replication material (124) during the formation of a replicated optical element on the aperture (142).

### TECHNICAL FIELD

This disclosure relates to replicated optical elements.

### BACKGROUND

Optical devices that include one or more optical light emitters and one or more optical sensors can be used in a wide range of applications including, for example, distance measurement, proximity sensing, gesture sensing, and imaging. Small optoelectronic modules such as imaging devices and light projectors employ optical assemblies that include lenses or other optical elements stacked along the device's optical axis to achieve desired optical performance. Replicated optical elements include transparent diffractive and/or refractive optical elements for influencing an optical beam. In some applications, such optoelectronic modules can be integrated into various consumer electronics, such as portable computing devices (e.g., smart phones, tablets, wearables, and laptop computers).

### SUMMARY

The present disclosure describes techniques for controlling the flow of replication material (e.g., epoxy) during the formation of replicated optical elements. In general, flow barriers such as trenches and/or walls laterally surrounding an aperture in a coating on a transparent substrate help control the flow of replication material during the formation of a replicated optical element on the aperture.

For example, in one aspect, the present disclosure describes a method including providing a transparent substrate having a coating on its surface, wherein the coating includes an aperture therein. The coating further has at least one trench therein, wherein the at least one trench laterally surrounds the aperture. The method includes using a replication technique to form an optical element on the transparent substrate in the aperture, the optical element being composed of replication material. The at least one trench serves as a barrier to flow of the replication material.

This disclosure also describes an apparatus including a transparent substrate having a coating on its surface, wherein the coating includes an aperture therein. The coating further has at least one trench therein, wherein the at least one trench laterally surrounds the aperture. A replicated optical element is on the transparent substrate and is disposed within the aperture. The optical element has a yard portion extending laterally in a direction from the aperture toward the at least one trench.

In another aspect, the present disclosure describes a method including providing a transparent substrate having a coating on its surface, wherein the coating includes an aperture therein. At least one wall is disposed on the coating and laterally surrounds the aperture. The method includes using a replication technique to form an optical element on the transparent substrate in the aperture, the optical element being composed of replication material. The at least one wall serves as a barrier to flow of the replication material.

The disclosure also describes an apparatus including a transparent substrate having a coating on its surface, wherein the coating includes an aperture therein. The coating further has at least one wall thereon, wherein the at least one wall laterally surrounds the aperture. A replicated optical element is on the transparent substrate and is disposed within the aperture. The optical element has a yard portion extending laterally in a direction from the aperture toward the at least one wall.

Some implementations include one or more of the following features. For example, in some cases, the apparatus includes a light emitting or light sensing device having an optical axis aligned with the optical element. In some implementations, there are a plurality of trenches laterally surrounding the aperture. The optical element can be, for example, a microlens array. In some instances, the coating is composed of a chrome.

Other aspects, features, advantages will be apparent from the detailed description, the accompanying drawings, and the claims.

### BRIEF DESCRIPTION OF THE DRAWINGS

FIG. 1 illustrates a cross-sectional view of a tool-substrate structure for replication.

FIG. 2 shows a replicated optical element having a yard portion.

FIG. 3 illustrates a cross-sectional view of a portion of the yard portion.

FIG. 4A is a top view of a substrate including flow barriers.

FIG. 4B is a cross-sectional view taken through the circle A of FIG. 4A showing the flow of replication material.

FIG. 5A illustrates a cross-sectional view of another implementation of flow barriers.

FIG. 5B is a cross-sectional view taken through the circle B of FIG. 5A showing the flow of replication material.

FIG. 6 shows a replicated optical element having a yard portion on a transparent substrate.

### DETAILED DESCRIPTION

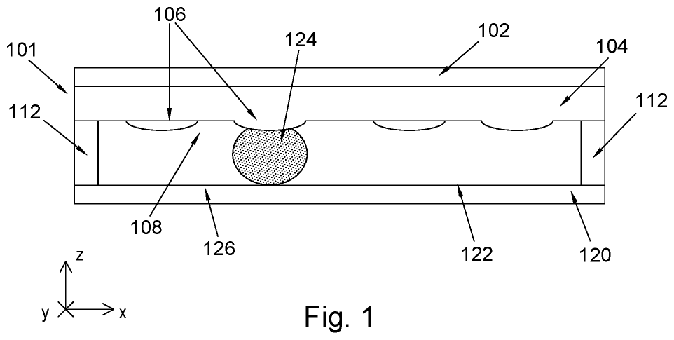

FIG. 1 schematically shows a cross section of a replication tool 101, and a transparent substrate 120 onto which optical elements are to formed by replication. The tool 101 includes a rigid or relatively hard back plate 102 composed of a first material, for example glass, and a replication portion 104 composed of a second, softer material, for example polydimethylsiloxane (PDMS). The relatively low stiffness of the replication portion 104 can allow the replication portion, under “normal” conditions (e.g., where no more pressure than the one caused by gravity forces of the tool lying on the substrate or vice-versa), to adapt to roughness, e.g., on a micrometer and/or sub-micrometer scale and, thus, may form an intimate connection to the substrate surface when they are brought into contact with one another.

The replication portion 104 forms a replication surface 108 including replication sections 106, the surface of each of which is a (negative) copy of a surface shape an optical element to be manufactured by replication. The optical elements to be manufactured by replication may be, for example, lenses, diffusers, or other optical elements. In some instances, each optical element to be replicated is a microlens array (MLA). In some cases, the replication sections 106 can be, for example, convex and thus define a concave optical element surface, or can be convex and define a concave optical element surface.

The replication portion 104 has contact spacer portions 112 arranged peripherally. The contact spacer portions 112 are the structures of the replication tool 101 that protrude the furthest from the tool 101 along the z axis. The contact spacer portions 112 are essentially flat and, thus, are operable to rest against the substrate 120 during replication, with no material between the contact spacer portions 112 and the substrate 120. The contact spacer portions 112 may, for example, form a ring laterally surrounding the periphery of the replication surface 108, or may form discrete portions around the periphery.

The substrate 120 has a first side (e.g., substrate surface 126) and a second side and can be composed of any suitable material, for example glass. The substrate surface 126 may have a structure to which the replica is to be aligned. The structure may, for example, comprise a coating 122 structured in the x-y-plane, such as a screen with apertures, or a structured IR filter etc. The structure may in addition, or as an alternative, comprise further features like markings.

For replicating the replication surface 108 of the tool 101, replication material 124 is applied to the substrate 120 or the tool 101 or both the tool 101 and the substrate 120. Although a single portion of replication material 124 is illustrated in the figure, application of the replication material 124 may include applying multiple portions of replication material 124 (e.g., a respective portion for each of the replication sections 106). Each portion may, for example, be applied by dispensing (e.g., jetting) one or more droplets using a dispensing tool. The replication material 124 can be composed, for example, of epoxy.

After application of the replication material 124, the substrate 120 and the tool 101 are aligned with respect to one another, for example, at an alignment station. Subsequent to the alignment, the substrate 120 and the tool 101 are brought together, with the contact spacer portions 112 resting against the substrate surface so as to define the height in the z dimension and also to lock the tool against x-y-movements. After the replication tool 101 and the substrate 120 have been moved towards each other with the replication material 124 between them, the substrate-tool-assembly can be removed from the alignment station and transferred to a hardening station, where the replication material 124 is hardened (e.g., cured). The replication tool 101 then can be removed.

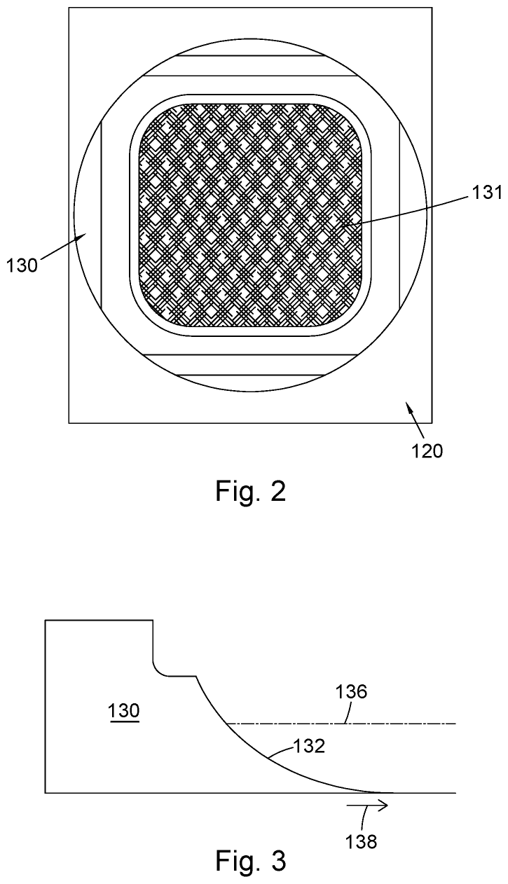

Referring to FIG. 2, during replication, excess replication material or epoxy applied, for example, during jetting normally overflows the region of interest and forms a yard 130 when the tool and the substrate 120 are brought into contact. The yard 130 sometimes is annular or ring shaped and laterally surrounds the optical element 131. The yard 130 results from more epoxy 124 being added during the replication process than each replicated structure (e.g., optical element) requires, causing an overflow. The additional epoxy ensures that the complete volume of replication material needed for a particular structure is available (as the tolerance of the epoxy volume is not zero), and the extra fluid pools to form the yard 130.

FIG. 3 illustrates a cross-sectional view of a portion of the yard 130, which sometimes includes a relatively thin membrane or overflow region 132. The overflow region 132 may have a thickness on the order of less than 5 μm, with outer portions of the region 132 having a thickness of less than 1 μm. The epoxy used as the replication material 124 typically includes a photo-initiator, which allows the epoxy to be cured, for example, by the application of ultra-violet (UV) radiation. However, for thin sections of the yard (e.g., overflow region 132), there may be little or no photo-initiator present, such that the replication material 124 is not fully cured, and remains in a liquid state, even after application of the UV radiation. In the example of FIG. 3, the dashed-dotted line 136 indicates the minimum height of the replication material required for UV curing to be effective. The failure to achieve complete curing of the replication material 124 can be problematic, for example, because the epoxy may flow out to the edge of the module and may result in reliability issues. In FIG. 3, the arrow 138 indicates the direction of flow of uncured replication material.

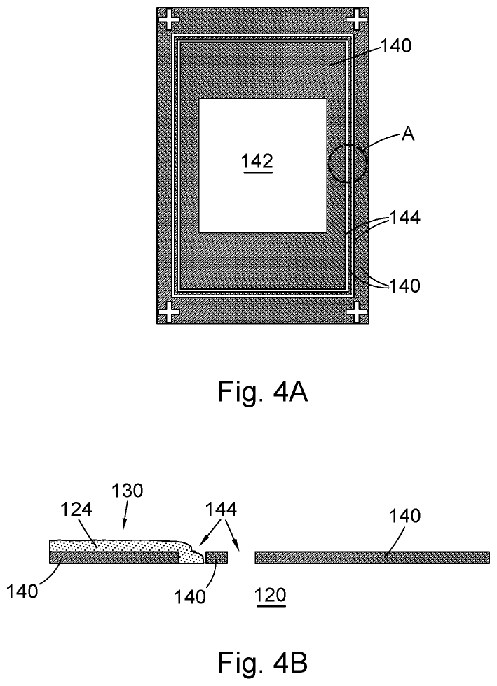

To help prevent the formation of thin membrane or thin overflow regions 132 during the replication process, flow barriers can be provided on the substrate 120 so as to control the flow of the epoxy. A first example is illustrated in FIGS. 4A and 4B. As shown in FIG. 4A, a metal (e.g., a compound or alloy of chromium; chrome) 140 may be provided on the surface of the glass substrate 120. Respective openings in the coating 140 (e.g., opening 142) define apertures onto which the optical elements are replicated. The apertures 142 can be formed, for example, by selectively etching the chrome coating 140 using standard etchants (e.g., ceric ammonium nitrate). During the replication process, some of the replication material (e.g., the epoxy) is dispensed or flows onto the surrounding coating 140 and forms the yard portion of the replicated element. As shown in FIGS. 4A and 4B, one or more rectangular or annular trenches 144 laterally surround each respective aperture 142 so as to control the flow of the replication material 124 and, preferably, prevent formation of very thin overflow regions. The trenches 144 can be formed, for example, by selectively etching away the chrome coating 140 at the same time the apertures 142 are formed. The concave step(s) provided by the trench(s) 144 allow excess epoxy from the overflow replication material 124 to flow into, and accumulate in, the trench(es) 144 so as to reduce the likelihood of very thin (e.g., <5 μm) regions of epoxy forming at the perimeter of the yard 130. The presence of the trenches 144 in the coating 140 thus provides barriers to the flow of the replication material 124. In some instances, a single trench 144 may be sufficient. In other cases, it may be beneficial to provide two or more trenches 144, as shown in FIG. 4B.

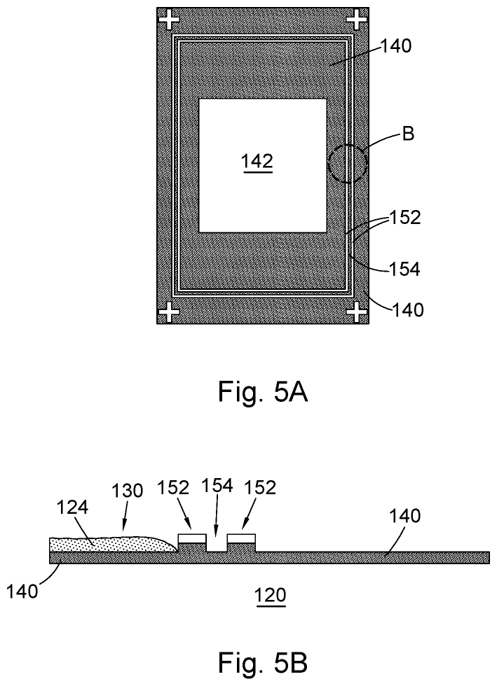

In some instances, instead of forming trenches 144 in the chrome coating 140, one or more layers are added selectively over portions of the chrome coating 140 so as to form one or more respective walls 152 encircling the aperture 142 on which the optical element is replicated (see FIGS. 5A and 5B). The additional layer(s) for the walls 152 can include, for example, SiO₂, chrome and/or gold, depending on the particular application. Other materials also can be used for the walls 152. The presence of the walls 152 on the coating 140 thus provides barriers to the flow of the replication material 124. If more than one wall 152 is present, the walls 152 can be separated by a narrow space 154, which also can help control the flow of replication material 124 in the event, e.g., some of the replication material flows over one of the walls.

In some instances, the presence of the replication material flow barriers (144 and/or 152) can help improve the yield in the manufacturing process. The flow barriers also can serve as guidelines for visual inspection during the manufacture process, and in some cases, can help increase the accuracy of such inspections and may reduce manual inspection times.

The foregoing techniques can be performed, for example, at a wafer-level in which a glass or other transparent substrate has a metal (e.g., chrome) coating on its surface, where the coating has multiple apertures therein, each of which is surrounded by a respective one or more trenches (or walls) that serve as barriers to help control the follow of the replication material (e.g., epoxy) during the replication process. An optical element (e.g., a MLA) is replicated onto each of the apertures. The sub-assembly, including the transparent substrate having the replicated optical elements on its surface, then can be attached, for example, to another substrate (e.g., a printed circuit board) on which are mounted multiple light emitting devices (e.g., VCSELs, laser diodes, or LEDs). Each of the optical elements is aligned to an optical axis of a respective one of the light emitting devices. The stack of substrates then can be separated (e.g., by dicing) to form individual modules or packages each of which includes a light emitting device and an optical element. In this context, the substrate is “transparent” in the sense that it is substantially transparent to a wavelength of radiation (e.g., visible, infra-red (IR) or ultra-violet (UV)) emitted by the light emitting device.

In some implementations, the transparent substrate having the replicated optical elements on its surface is separated into individual units each of which includes a single one of the replicated optical elements (e.g., MLAs). The replicated optical elements then can be positioned (e.g., by pick-and-place equipment), for example, over a light emitter such as a VCSEL, an LED or laser diode as part of an optoelectronic package.

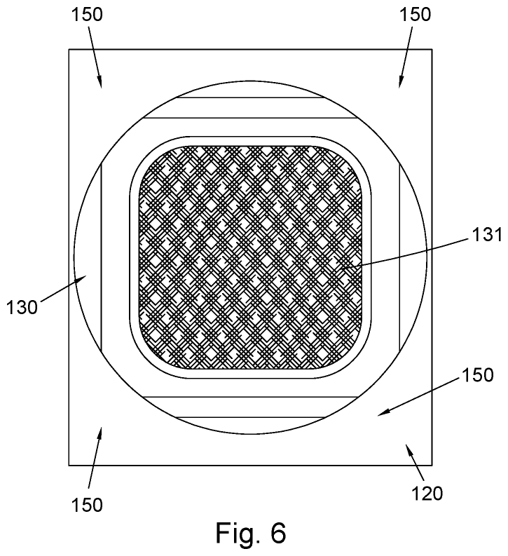

Providing barriers (144 and/or 152) as described below to control or restrict the flow of the replication material 124 can be advantageous for additional reasons as well. The replication material flow barriers can be useful in defining the outline or lateral shape of the replication material on the substrate 120. Thus, in some instances, the outline of the replication material can be set such that regions of the substrate 120 remain uncovered by the replication material. For example, as shown in FIG. 6, even accounting for the yard portion 130 of the optical element 131, regions 150 of the transparent substrate 120 will not be covered by the excess replication material (i.e., the yard 130). When the substrate 120 is singulated into individual optical units, the substrate can be diced along lines that do not cut through the replication material, including the yard 130. This technique can be advantageous because it can help reduce the likelihood that the replication material (e.g., the epoxy) delaminates. Further, the regions 150 of the substrate 120 where there is no replication material present can be used to clamp the optical unit during its assembly into an optoelectronic module so as to hold the optical unit in place. Avoiding attaching, for example, a jig to regions of the substrate 120 where replication material is present can help reduce the occurrence of reliability problems.

In some instances, a sub-assembly, including the transparent substrate having the replicated optical elements on its surface, is attached, for example, to another substrate (e.g., a printed circuit board) on which are mounted multiple light (e.g., visible, IR or UV) sensors. In this context, the substrate is “transparent” in the sense that it is substantially transparent to a wavelength of radiation (e.g., visible, infra-red (IR) or ultra-violet (UV)) detectable by the light sensor.

Other implementations are within the scope of the claims.

1. A method comprising:
providing a transparent substrate having a coating on its surface, wherein the coating includes an aperture therein, the coating further having at least one trench therein, wherein the at least one trench laterally surrounds the aperture; and
using a replication technique to form an optical element on the transparent substrate in the aperture, the optical element being composed of replication material;
wherein the at least one trench serves as a barrier to flow of the replication material.

2. The method of claim 1 wherein, during the replication technique, some of the replication material flows over the coating and into the at least one trench.

3. The method of claim 1 wherein there are a plurality of trenches laterally surrounding the aperture.

4. The method of claims 1 wherein the optical element is a microlens array.

5. The method of claims 1 wherein the coating is composed of a chrome.

6. An apparatus comprising:
a transparent substrate having a coating on its surface, wherein the coating includes an aperture therein, the coating further having at least one trench therein, wherein the at least one trench laterally surrounds the aperture; and
a replicated optical element on the transparent substrate disposed within the aperture, wherein the optical element has a yard portion extending laterally in a direction from the aperture toward the at least one trench.

7. The apparatus of claim 6 further including a light emitting or light sensing device having an optical axis aligned with the optical element.

8. The apparatus of claim 6 including a plurality of trenches laterally surrounding the aperture.

9. The apparatus of claim 6 wherein the optical element is a microlens array.

10. The apparatus of claim 6 wherein the coating is composed of a chrome.

11.-15. (canceled)

16. An apparatus comprising:
a transparent substrate having a coating on its surface, wherein the coating includes an aperture therein, the coating further having at least one wall thereon, wherein the at least one wall laterally surrounds the aperture; and
a replicated optical element on the transparent substrate disposed within the aperture, wherein the optical element has a yard portion extending laterally in a direction from the aperture toward the at least one wall.

17. The apparatus of claim 16 further including a light emitting or light sensing device having an optical axis aligned with the optical element.

18. The apparatus of claim 16 including a plurality of walls laterally surrounding the aperture.

19. The apparatus of claim 16 wherein the optical element is a microlens array.

20. The apparatus of claim 16 wherein the coating is composed of a chrome.
